(19) United States
(12) Patent Application Publication
(10) Pub. No.: US 2010/0065096 A1
(43) Pub. Date: Mar. 18, 2010

(54) THERMO ELECTRIC GENERATOR AND METHOD

(76) Inventor: Gerald N. Pellegrini, Worcester, MA (US)

Correspondence Address: Gerald N. Pellegrini, 37 Granby Road, Worchester, MA, 01604, US

(21) Appl. No.: 12/212,208

(22) Filed: Sep. 17, 2008

(51) Int. Cl. H01L 35/34; H01L 35/30

(52) U.S. Cl. 136/201; 136/205

(57) ABSTRACT

A thermo-electric generator that utilizes statistically driven electric currents to create potential differences in a circuit. These statistically driven electric currents are endothermic and absorb thermal energy. The created potential differences are utilized to generate electric field driven electric currents to perform useful work in an electrical load. The energy supplied to the load is the net thermal energy absorbed in the circuit.

### BACKGROUND OF THE INVENTION

### Background Information

Thermo-electric generators are not new. Well known thermo-couples convert thermal energy to electrical energy by utilization of the net potential differences generated in an electric circuit due to a difference in the temperatures of junctions between dissimilar metals. There are also thermoelectric generators that use semiconductor materials. However, these generators require a temperature difference in different regions of the generator. The “driving force” of the electrical potential generated to drive a load in these devices is this temperature difference. Also, the efficiency of conversion of thermal energy to electrical energy of these devices is limited by the differences in the high and low temperatures in the system. It would be advantageous to be able to generate potential differences within a circuit that are not the result of temperature differences within the system. It is the object of the invention to utilize statistically driven currents to generate the potential differences required to provide electrical energy to a load.

### SUMMARY OF THE INVENTION

The present invention makes use of endothermic statistically driven currents to generate potential differences in an electrical circuit. Statistically driven currents are those currents that flow not by electrical forces but by “probabilistic influences” that redistribute charges to maintain a more probable state. These endothermic statistically driven currents will in turn produce a net electrical potential difference that is utilized in the invention to provide electrical energy to a load. This is accomplished by maintaining a net statistically driven current (or diffusion current) in one portion of an electrical circuit and a net electric field driven current in another portion of the circuit. The result being that thermal energy is absorbed in the endothermic statistically driven current portion of the circuit and electrical energy is utilized in the electric field driven current portion of the circuit through an electrical load.

### BRIEF DESCRIPTION OF THE DRAWINGS

The invention description below refers to the accompanying drawings, of which:

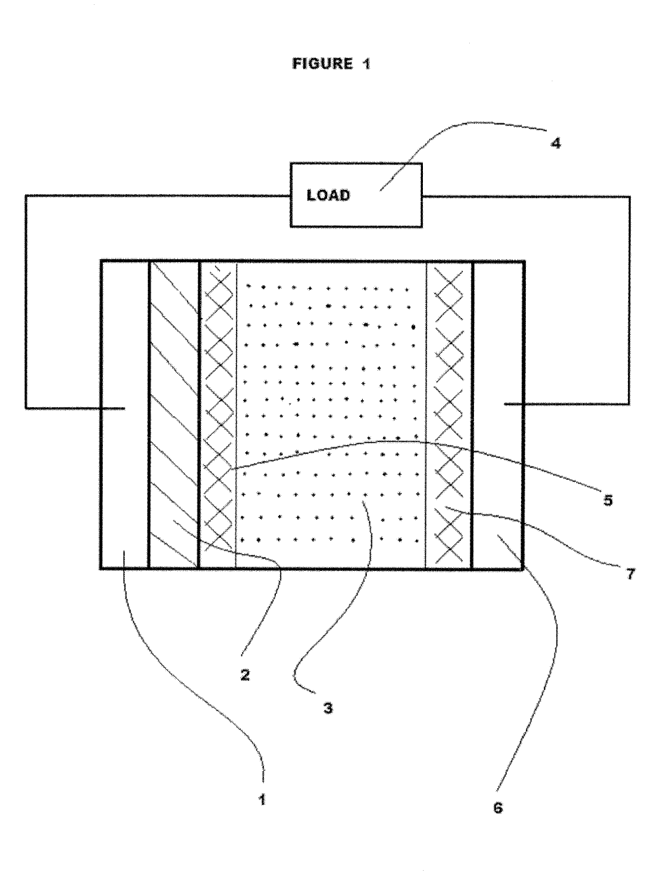

The drawing (FIG. 1) is a drawing of the preferred embodiment of the invention. The drawing illustrates a semiconductor structure containing gold conductor elements (references 1 and 6), a properly doped semiconductor material (reference 3), semiconductor depletion regions (references 5 and 7), an interfacial oxide layer (reference 2), and an electrical load (reference 4)

### DETAILED DESCRIPTION OF AN ILLUSTRATIVE EMBODIMENT

The invention relates to generating electric energy through the use of statistically driven electric currents. It is known that electric currents may be generated by non-equilibrium distributions of charge carriers. In semiconductors, for example, when a non-uniform density of charge carriers exists in the semiconductor, a diffusion current is generated. This diffusion current is not driven by electrical potential differences and therefore “spontaneous” (i.e., driven by the fact that the charge distribution does not represent the most probable distribution of charge carriers even though the total charge density is zero and there is no net electric potential differences or electric field). This “statistically” driven diffusion current will redistribute charge spontaneously creating electric potential differences. This potential in turn establishes an electric field driven current in the semiconductor opposed to the diffusion current. Normally an equilibrium condition is created where the statistically driven diffusion current creates an electric potential sufficient to maintain a field driven current equal and opposite to the diffusion current. Under these equilibrium conditions the electric potential differences created by the “statistically” driven diffusion current will be maximum. The field driven current which flows from a higher electrical potential to a lower electrical potential is exothermic (spontaneously generates heat), and the diffusion current that flows from a lower electrical potential to a higher electrical potential is endothermic (spontaneously absorbs heat). In equilibrium, the heat generated by the field driven current equals the heat absorbed by the diffusion current and no net heat is generated, or absorbed.

In the invention, an alternative path for the field driven current is created in which a field driven current is maintained separate from the path of the diffusion current. Under these circumstances a steady-state condition is established in which the diffusion current and the field driven current do not cancel locally. This can be explained as follows. The alternative path for the field driven current can be made of sufficient conductance such that the electric potential difference generated by the diffusion current cannot be maintained at its maximum level to locally generate a field driven current sufficient to cancel the diffusion current. The result being that a net diffusion current is maintained at some value of the electric potential difference below the maximum value in a portion of the electrical circuit. The field driven current flowing in the alternative path in a second portion of the circuit would equal the net diffusion current and a resultant steady-state circulatory current is established in the circuit.

As already described, the diffusion current is endothermic. In this endothermic process electric current flows from a lower electrical potential to a higher electrical potential in the portion of the circuit containing the diffusion current resulting in heat energy being absorbed and transformed into electrical energy. This electrical energy can be stored or utilized as any other form of electrical energy. The net result of the above mentioned process is the conversion of heat energy to useful electrical energy.

An example of the above circuit can be described as follows. Consider a semiconductor device consisting of a metal conductor interfaced with a semiconductor material, and a second interface to a similar metal conductor. Built-in potential differences or voltages will in general be generated at each of the metal-semiconductor interfaces and along the semiconductor material. The total built-in potential difference between the two similar metal conductors is the algebraic sum of the individual built-in potential differences. This sum may be non-zero depending upon the type of contacts, or interfaces, made between the metal conductors and the semiconductor and the type of semiconductor used. The built-in potential difference in the semiconductor depends on the variations of intrinsic electric charge carrier concentrations of the semiconductor and the resulting diffusion currents. Also, the built-in potential differences between a metal conductor and a particular semiconductor depends upon the type of the metal used, the type of interfacing between metal and semiconductor, and whether the contact between metal and semiconductor is, or to what extent, an “Ohmic contact”. Consequently, the total built-in potential difference between the two similar metal conductors, being the sum total of all the built-in potential differences need not be zero. Under these circumstances an external load may be connected across the two metal conductors creating the above mentioned alternation path and a net electric field driven current in the above described circuit.

A preferred embodiment of how this circuit can be achieved is as follows (See FIG. 1). The magnitude of the built-in potential difference created between gold conductors (References 1 and 6) and properly doped silicon (Reference 3), for example, depends upon whether an interfacial oxide layer (Reference 2) exists between the gold conductor and the silicon. The built-in potential difference between the silicon (Reference 3) and the gold conductor (Reference 1) is greater than the built-in potential difference between the silicon (Reference 3) and the gold conductor (Reference 6). The built-in potential difference between the silicon (Reference 3) and the gold conductor (Reference 1) is distributed between the depletion region (Reference 5) and the oxide layer (Reference 2), whereas the built-in potential difference between the silicon (Reference 3) and the gold conductor (Reference 6) is only across the depletion region (Reference 7). Any metal depletion regions have been neglected as is usual done. A description of the dependence of built-in potential differences to interfacial oxide layers is contained in “Principles of Semiconductor Devices” by Bart Van Zeghbroeck, Chapter 3, section 3.7 “Schottky diode with an interfacial layer”. Since the magnitude of the built-in potential difference between the silicon and gold is greater with an oxide layer than without an oxide layer, the configuration shown in FIG. 1 will exhibit a net potential difference (voltage) between the gold conductor (Reference 1) and the gold conductor (Reference 6).

This net built-in potential difference does not require temperature gradients, since these built-in potentials (with and without an oxide layer) exist at constant temperature. This net built-in potential difference (voltage) can then be used to drive a field driven current through an external load (Reference 4) connected across the gold conductors and deliver electrical power as described above. The energy source of this power is the heat absorbed in the endothermic portion of the circuit (References 2 and 5) in which there is a net diffusion current. This net diffusion current flows from the region of the silicon (Reference 3) at lower electrical potential to the region of the gold conductor (Reference 1) at higher electrical potential.

What is claimed is:

1-6. (canceled)

7. A thermo-electric generator in which thermal energy is converted to useful energy comprising:
a first portion of an electrical circuit providing for a net voltage between electrical terminals, said voltage being generated by electric charge separation due to statistically driven currents in said portion;
a second portion of said circuit comprising an electrical load, said load being connected to said terminals and providing for a voltage driven current to flow between said terminals and through said load.

8. A generator as recited in claim 7 in which said statistically driven currents are diffusion currents.

9. A generator as recited in claim 7 in which said statistically driven currents are semiconductor diffusion currents.

10. A method for converting thermal energy to useful electrical energy comprising the steps of:
generating a net voltage between electrical terminals by electric charge separation due to statistically driven currents;
providing for a voltage driven current, said voltage driven current flowing between said terminals and through an electrical load.

11. A method as recited in claim 10 in which said statistically driven currents are diffusion currents.

12. A method as recited in claim 10 in which said statistically driven currents are semiconductor diffusion currents.
